(19) United States
(12) Patent Application Publication
(10) Pub. No.: US 2021/0135169 A1
(43) Pub. Date: May 6, 2021

(54) FORMING METHOD OF PROTECTION FILM FOR ORGANIC EL DEVICE, MANUFACTURING METHOD OF DISPLAY APPARATUS, AND DISPLAY APPARATUS

(71) Applicant: THE JAPAN STEEL WORKS, LTD., Shinagawa-ku, Tokyo (JP)

(72) Inventors: Keisuke WASHIO, Kanagawa (JP); Tatsuya MATSUMOTO, Kanagawa (JP); Toru MASHITA, Kanagawa (JP); Masamitsu TORAMARU, Kanagawa (JP)

(21) Appl. No.: 16/492,143

(22) PCT Filed: Mar. 7, 2018
(86) PCT No.: PCT/JP2018/008843

§ 371 Date: Sep. 8, 2019

(30) Foreign Application Priority Data
Mar. 23, 2017 (JP) 2017-057078
Mar. 6, 2018 (JP) 2018-039547

(51) Int. Cl. H01L 51/56; H01L 51/00; H01L 51/52

(52) U.S. Cl. CPC H01L 51/56; H01L 51/5253; H01L 51/0097

(57) ABSTRACT

An object is to improve performance of a protection film for an organic EL device. A forming method of the protection film for an organic EL device includes the steps of: (a) forming an organic EL device over a flexible substrate; and (b) forming a protection film including an SiOC film so as to cover the organic EL device. Moreover, the SiOC film is formed by an ALD method using a compound containing Si and C as a material, the compound containing Si and C has at least one or more C atoms in a main chain between Si atom and Si atom, and amino groups are respectively bonded to the Si atoms on both ends of the main chain. According to this method, carbon (C) can be effectively taken into an SiO film to be formed. This SiOC film has a moisture barrier property and flexibility. Thus, it is possible to protect the organic EL device from moisture, and its bending resistance can be improved. Moreover, the degree of flexibility can be adjusted by adjusting the number of C atoms in the main chain between Si atom and Si atom.

### TECHNICAL FIELD

The present invention relates to a forming method of a protection film for an organic EL device, a manufacturing method of a display apparatus, and a display apparatus.

### BACKGROUND ART

An organic electroluminescence device has been developed as a light emitting device. An electroluminescence refers to a light emitting phenomenon that occurs when a voltage is applied to a substance. A device that generates this light emitting phenomenon in an organic substance is referred to as an organic EL device (organic electroluminescence device). Since the organic EL device is a current injection device and also exerts diode characteristics, the organic EL device is referred to also as an organic light emitting diode (OLED).

Japanese Patent Application Laid-Open Publication No. 1996-048369 (Patent Document 1) has disclosed a technology in which a first layer made of only silicon oxide that is superior in adhesion to a base substrate, a second layer made of silicon oxide containing carbon that is superior in resistance to tension and bending, and a third layer made of only silicon oxide that is superior in adhesion to a printing layer and an adhesive layer are sequentially formed over the base substrate made of a transparent polymer material. Moreover, the silicon oxide layer of the first layer is a silicon dioxide (SiO₂) layer formed by PECVD using an organic silicon compound gas or a silane (SiH₄) gas and an oxygen gas as main source gases.

Furthermore, International Patent Application Publication No. 2004/017383 (Patent Document 2) has disclosed a technology relating to a low temperature atomic layer deposition (ALD) process for use in forming silicon oxide and/or silicon oxynitride from an organic silicon precursor and ozone. Moreover, as the organic silicon precursor, a material represented by the formula of Si(NR¹R²)_{4-W}L_{W} in which R¹ and R² are independently selected from the group of hydrogen, C₁-C₆ alkyl, C₅-C₆ cyclic alkyl, halogen, substituted alkyl and substituted cyclic alkyl, W is an integer of 1, 2, 3 or 4 and L is selected from hydrogen or halogen is exemplified.

### RELATED ART DOCUMENTS

### Patent Documents

Patent Document 1: Japanese Patent Application Laid-Open Publication No. 1996-048369

Patent Document 2: International Patent Application Publication No. 2004/017383

### SUMMARY OF THE INVENTION

### Problems to be Solved by the Invention

A display apparatus using organic EL devices is applied to an information equipment or the like, and has been enhanced in flexibility. Such a flexible organic EL display is expected to be applied not only to a mobile-use apparatus, but also to a large-size display-use apparatus.

In order to achieve the flexible structure described above, a protection film for the organic EL device is required to satisfy the moisture barrier property for preventing entrance of moisture and the flexibility to meet the requirement for the flexible structure, and developments of the protection film that satisfies both of them have been desired.

The other problems and novel features will become apparent from the description of the present specification and the accompanying drawings.

### Means for Solving the Problems

A forming method of a protection film for an organic EL device according to one embodiment of the present invention includes the steps of: (a) forming an organic EL device over a flexible substrate; and (b) forming a protection film including an SiOC film so as to cover the organic EL device. Moreover, the SiOC film is formed by an ALD method using a compound containing Si and C as a material, the compound containing Si and C has at least one or more C atoms in a main chain between Si atom and Si atom, and amino groups are respectively bonded to the Si atoms on both ends of the main chain.

A manufacturing method of a display apparatus according to one embodiment of the present invention includes the steps of: (a) forming an organic EL device over a flexible substrate; and (b) forming a protection film including an SiOC film so as to cover the organic EL device. Moreover, the SiOC film is formed by an ALD method using a compound containing Si and C as a material, the compound containing Si and C has at least one or more C atoms in a main chain between Si atom and Si atom, and amino groups are respectively bonded to the Si atoms on both ends of the main chain.

A display apparatus according to one embodiment of the present invention includes: a flexible substrate; an organic EL device formed over the flexible substrate; and a protection film formed so as to cover the organic EL device and including an SiOC film. Moreover, the SiOC film is formed by an ALD method using a compound containing Si and C as a material, the compound containing Si and C has at least one or more C atoms in a main chain between Si atom and Si atom, and amino groups are respectively bonded to the Si atoms on both ends of the main chain.

### Effects of the Invention

According to one embodiment of the present invention, it is possible to improve the performance of the protection film for the organic EL device.

### BRIEF DESCRIPTIONS OF THE DRAWINGS

FIG. 1 is a cross-sectional view of a protection film for an organic EL device according to a first embodiment;

FIG. 2 is a diagram schematically showing a structure of a compound containing Si and C, which is a material of the protection film for the organic EL device according to the first embodiment;

FIG. 3(a) to FIG. 3(d) are diagrams showing a DMSE structure and a reaction system for forming an SiOC film using DMSE;

FIG. 4(a) to FIG. 4(d) are diagrams schematically showing a state of the film formation of the SiOC film by the ALD method using the DMSE;

FIG. 5 is a plan view showing the entire configuration of a display apparatus according to a second embodiment;

FIG. 6 is a plan view showing an essential part of the display apparatus;

FIG. 7 is a cross-sectional view showing the essential part of the display apparatus;

FIG. 8 is a cross-sectional view showing an essential part of a manufacturing process of the display apparatus according to the second embodiment;

FIG. 9 is a cross-sectional view showing the essential part of the manufacturing process of the display apparatus according to the second embodiment;

FIG. 10 is a cross-sectional view showing the essential part of the manufacturing process of the display apparatus according to the second embodiment;

FIG. 11 is a cross-sectional view showing the essential part of the manufacturing process of the display apparatus according to the second embodiment;

FIG. 12 is a cross-sectional view showing the essential part of the manufacturing process of the display apparatus according to the second embodiment;

FIG. 13 is a cross-sectional view showing the essential part of the manufacturing process of the display apparatus according to the second embodiment;

FIG. 14 is a cross-sectional view showing one example of a configuration of a chamber for forming a film by the ALD method;

FIG. 15 is a diagram showing a foreign matter over an organic EL formation layer;

FIG. 16 is a diagram showing a case where a protection film is formed over the foreign matter over the organic EL formation layer by using the CVD method;

FIG. 17 is a diagram showing a case where a protection film is formed over the foreign matter over the organic EL formation layer by using the ALD method;

FIG. 18 is a cross-sectional view showing a protection film for an organic EL device according to a first example of a third embodiment;

FIG. 19 is a cross-sectional view showing a protection film for an organic EL device according to a second example of the third embodiment;

FIG. 20 is a cross-sectional view showing a protection film for an organic EL device according to a third example of the third embodiment;

FIG. 21 is a cross-sectional view showing a protection film for an organic EL device according to a fourth example of the third embodiment;

FIG. 22(a) to FIG. 22(d) are diagrams schematically showing a state of a formation of an SiO₂ film by the ALD method using bis(dimethylamino)silane;

FIG. 23 is a schematic diagram showing a state of a bending test;

FIG. 24(a) and FIG. 24(b) are cross-sectional views showing a PEN substrate in which an SiOC film and an Al₂O₃ film are stacked and a PEN substrate in which an Al₂O₃ film is formed as a single layer; and

FIG. 25(a) and FIG. 25(b) are surface photographs after the bending test of the PEN substrate in which an SiOC film and an Al₂O₃ film are stacked and the PEN substrate in which an Al₂O₃ film is formed as a single layer.

### DETAILED DESCRIPTION OF PREFERRED EMBODIMENTS

Hereinafter, embodiments of the present invention will be described in detail with reference to the drawings. Note that component shaving the same function are denoted by the same reference characters throughout the drawings for describing the embodiments, and the repetitive description thereof will be omitted.

### First Embodiment

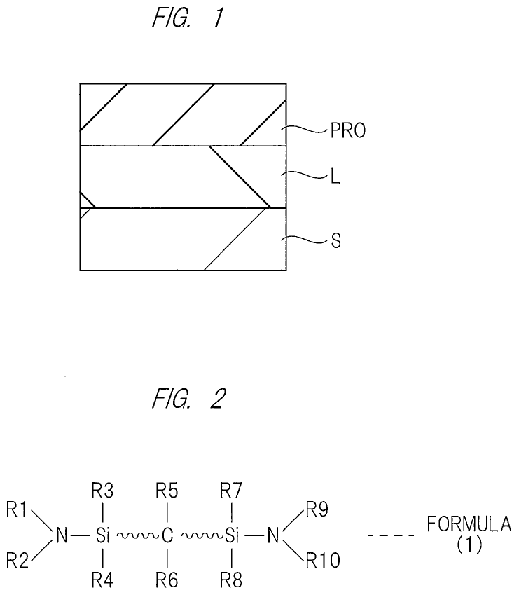

FIG. 1 is a cross-sectional view of a protection film for an organic EL device according to the present embodiment. As shown in FIG. 1, a protection film PRO for an organic EL device is formed over an organic EL formation layer L over a flexible substrate S.

This protection film PRO is made of an SiOC film formed by an ALD (Atomic Layer Deposition) method. This SiOC film is a film formed by the ALD method using a compound containing Si and C as a material. In this manner, a film containing carbon (C) is referred to as an organic film, and a method of forming an organic film by the ALD method is referred to as an organic ALD method. Moreover, the compound containing Si and C has two characteristics of (1) at least one or more C atoms are provided in a main chain between Si atom and Si atom and (2) amino groups are respectively bonded to Si atoms on both ends of the main chain.

FIG. 2 schematically shows a structure of the compound containing Si and C, which is a material of the protection film for the organic EL device according to the present embodiment.

One example of the silicon compound represented by formula (1) of FIG. 2 is 1,2-bis[(dimethylamino)dimethylsilyl]ethane (hereinafter, referred to simply as “DMSE”).

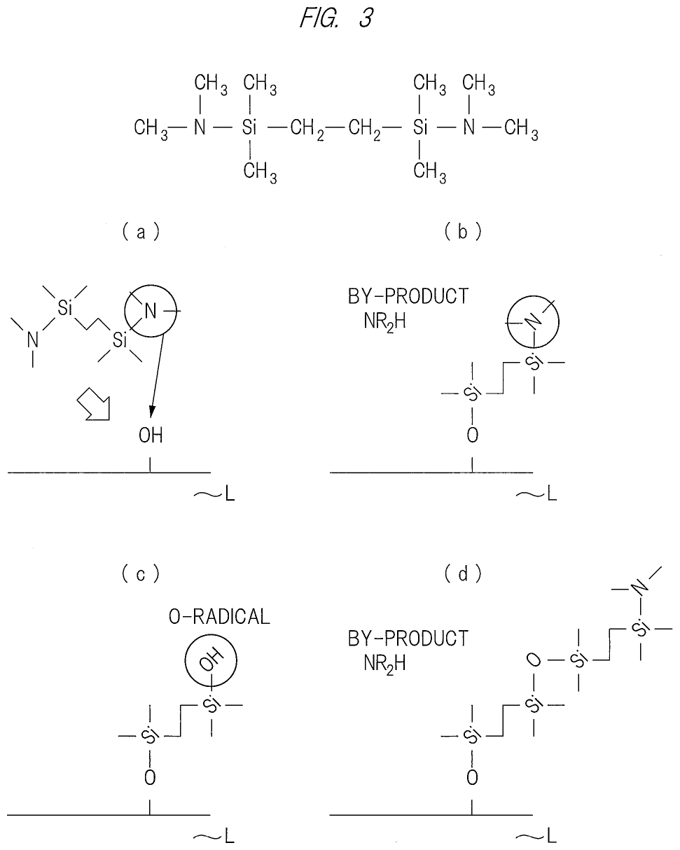

FIG. 3(a) to FIG. 3(d) are diagrams showing a DMSE structure and a reaction system for forming an SiOC film using DMSE. As shown in FIG. 3, (a) —OH on the surface of an organic EL formation layer L reacts with an amino group on one of the ends of DMSE to generate N(CH₃)₂H as a by-product (b). Next, as shown in (c), by the action of an oxygen radical (O-radical) serving as an oxidant, an amino group on the other end of DMSE forms —OH. Next, by allowing this —OH to react with another DMSE in the same manner as (a), an SiOC film is grown (d). Additionally, in FIG. 3, a reaction in which mutual Si atoms between adjacent atoms are directly bonded or bonded with another atom (for example, O or C) interposed therebetween may be generated. Moreover, although its probability is small, there is also a case where both of the amino groups on both ends of the above-mentioned material molecule sometimes react with —OH on the surface of the organic EL formation layer L.

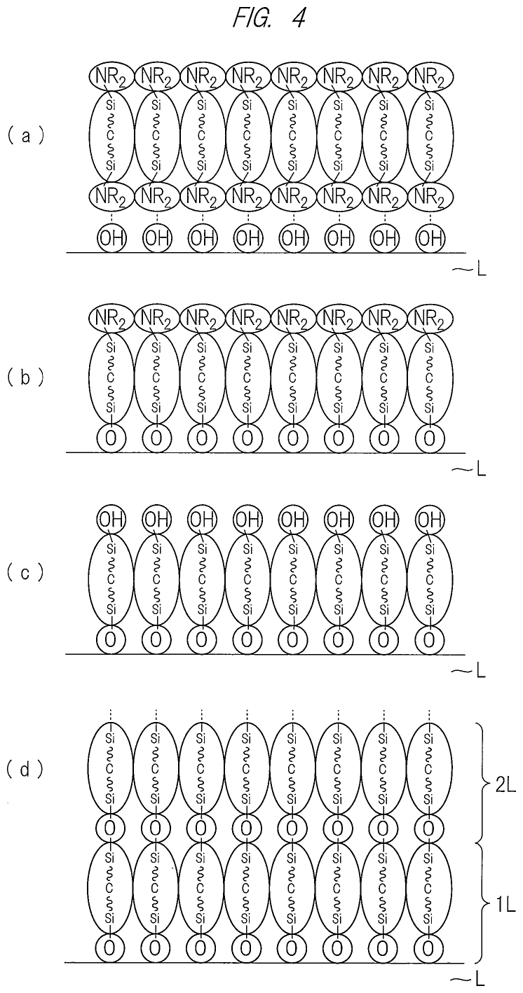

FIG. 4(a) to FIG. 4(d) are diagrams schematically showing a state of the film formation of the SiOC film by the ALD method using the DMSE.

First, as a first step (source gas supply step), DMSE serving as a source gas is introduced (supplied) into a chamber in which a substrate is disposed. Thus, molecules of the DMSE are physically adsorbed to the surface of the organic EL formation layer L that is a processing object (FIG. 4(a)). Then, —OH on the surface of the organic EL formation layer L and an amino group on one of the ends of DMSE react with each other and NR₂H (R=CH₃) is separated, so that O (oxygen atom) and Si (silicon atom) are chemically bonded with each other (FIG. 4(b)).

Next, as a second step (purging step), the introduction of the source gas into the chamber is stopped, and a purge gas is introduced (supplied) thereto. As the purge gas, an inert gas is suitably used; however, a nitrogen gas (N₂ gas) may be used in some cases. By introducing the purge gas, the source gas other than the DMSE reacted with —OH on the surface of the organic EL formation layer L and a by-product NR₂H(R=CH₃) are discharged to the outside of the chamber together with the purge gas.

Next, as a third step (reaction gas supply step), a reaction gas is introduced (supplied) into the chamber. As the reaction gas, O-plasma may be used. In this case, an O₂ gas (oxygen gas) is introduced into the chamber, and O-plasma is generated by applying high-frequency power. Note that O-plasma preliminarily generated outside the chamber may be introduced (supplied) into the chamber. By the action (reaction) of this O-plasma, an amino group on the other end of DMSE becomes —OH (FIG. 4(c)). In other words, a reactant with O-radical is generated. Thus, an atomic layer (first layer 1L) of SiOC is formed over the surface of the organic EL formation layer L. Note that an O₃ gas (ozone gas) or vapor (H₂O) may be used in place of O₂ gas (oxygen gas). However, in the film formation at a low temperature (for example, 200° C. or lower), the reactivity becomes better in the case where the O-plasma derived from O₂ gas is used.

Next, as a fourth step (purging step), the introduction of the reaction gas into the chamber and the application of the high-frequency power are stopped, and a purge gas is introduced (supplied) into the chamber. As the purge gas, an inert gas is suitably used; however, a nitrogen gas (N₂ gas) may be used in some cases. By introducing the purge gas, an unreacted substance (reaction gas or the like) is discharged (purged) to the outside of the chamber together with the purge gas.

Next, by performing the first step, the second step, the third step and the fourth step in the same manner, an atomic layer (second layer) 2L of SiOC is formed (FIG. 4(d)).

As described above, by repeating the first, second, third and fourth steps for a plurality of cycles, an SiOC film having a desired film thickness can be formed over the surface of the organic EL formation layer L. For example, if the first, second, third and fourth steps are repeated for 30 cycles, a film composed of 30 atomic layers can be formed.

In this manner, according to the manufacturing method (forming method) of the protection film for an organic EL device of the present embodiment, since the material having at least one or more C atoms in a main chain between Si atom and Si atom is used, carbon (C) can be effectively taken into an SiOC film to be formed. This SiOC film has a moisture barrier property (water resistant property) and also has flexibility. Thus, it is possible to protect the organic EL device from moisture, and also possible to prevent cracking or the like due to bending even when a bending stress is applied to the SiOC film together with the flexible substrate, and consequently to improve the bending resistance.

Moreover, it is possible to adjust the flexibility by adjusting the number of C atoms in the main chain between Si atom and Si atom. For example, by increasing the number of C atoms in the main chain between Si atom and Si atom, the flexibility can be improved.

Furthermore, according to the manufacturing method of a protection film for the organic EL device of the present embodiment, since the molecule length becomes comparatively larger due to the main chain between Si atom and Si atom, the thickness of the atomic layer per one cycle can be made larger, and the film-forming speed of the SiOC film can be improved (see FIG. 4).

Note that a benzene ring or the like may be included in the main chain between Si atom and Si atom in addition to —C—, —C—C—, —C—C—C— or the like. Moreover, a compound of carbon and oxygen such as —O—C—C—O— or the like may be included.

Furthermore, the above-mentioned flexible substrate may be repeatedly bent, and can be regarded as a bendable substrate. Also, it may be folded, and can be regarded as a foldable substrate. As described above, the flexible substrate comprehensively includes the bendable substrate and the foldable substrate.

Moreover, the protection film for the organic EL device according to the present embodiment can be widely applicable to the display apparatus to be described later or electronic equipment such as illumination apparatus using the organic EL device.

### Second Embodiment

Next, a display apparatus having the protection film described in the first embodiment will be described below in detail.

<Structure of Display Apparatus>

The display apparatus of the present embodiment is an organic EL display apparatus (an organic electroluminescence display apparatus) utilizing an organic EL device. The display apparatus according to the present embodiment will be described with reference to drawings.

FIG. 5 is a plan view showing the entire configuration of a display apparatus 1 according to the present embodiment.

The display apparatus 1 shown in FIG. 5 includes a display unit 2 and a circuit unit 3. In the display unit 2, a plurality of pixels are arranged in an array, which makes it possible to display an image. In the circuit unit 3, various kinds of circuits are formed as needed, and for example, a driving circuit, a control circuit and the like are formed. The circuits in the circuit unit 3 are connected to the pixels of the display unit 2 as appropriate. The circuit unit 3 may be installed outside the display apparatus 1. Various shapes may be adopted as the plane shape of the display apparatus 1, and for example, a rectangular shape is used.

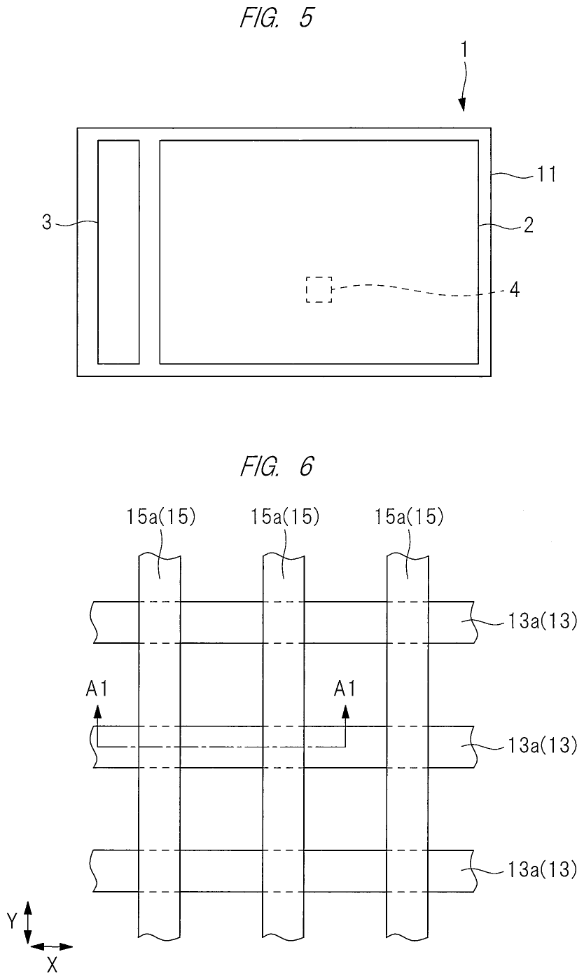

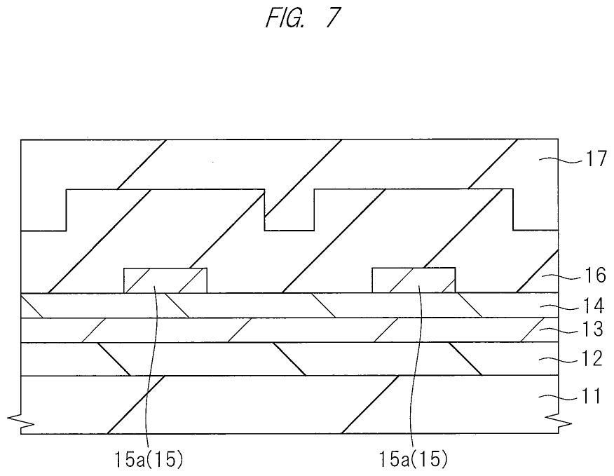

FIG. 6 is a plan view showing an essential part of the display apparatus 1, and FIG. 7 is a cross-sectional view showing the essential part of the display apparatus 1. FIG. 6 shows a part of the display unit 2 of the display apparatus 1 (region 4 shown in FIG. 5) in an enlarged manner. FIG. 7 corresponds to, for example, a part taken along line A1-A1 of FIG. 6.

A substrate 11 forming the base of the display apparatus 1 has an insulating property. Moreover, the substrate 11 is a flexible substrate (film substrate), and has flexibility. Therefore, the substrate 11 is a flexible substrate having the insulating property, that is, a flexible insulating substrate. The substrate 11 may also have translucency in some cases. As the substrate 11, for example, a film-shaped plastic substrate (plastic film) may be used. The substrate 11 is present over the entire plane of the display apparatus 1 of FIG. 5, and forms the lowest layer of the display apparatus 1. Therefore, the plane shape of the substrate 11 is substantially the same as the plane shape of the display apparatus 1, and various shapes, for example, a rectangular shape may be adopted. Note that, of the two main surfaces located on mutually opposed sides of the substrate 11, the main surface on the side where the organic EL devices are disposed, that is, the main surface over which a passivation film 12, an electrode layer 13, an organic layer 14, an electrode layer 15 and a protection film 16 to be described later are formed is referred to as an upper surface of the substrate 11. Moreover, the main surface on the side opposite to the upper surface of the substrate 11 is referred to as a lower surface of the substrate 11.

The passivation film (passivation layer) 12 is formed over the upper surface of the substrate 11. The passivation film 12 is composed of an insulating material (insulating film), for example, a silicon oxide film. Although the passivation film 12 may not be formed in some cases, it is more preferable to form the passivation film 12. The passivation film 12 may be formed over substantially the entire upper surface of the substrate 11.

The passivation film 12 has a function of preventing (blocking) the transmission of moisture from the side of the substrate 11 toward the organic EL device (in particular, the organic layer 14). Thus, the passivation film 12 can function as a protection film on the lower side of the organic EL device. On the other hand, the protection film 16 to be described later can function as a protection film on the upper side of the organic EL device, and has a function of preventing (blocking) the transmission of moisture from the upper side toward the organic EL device (in particular, the organic layer 14).

The organic EL device is formed over the upper surface of the substrate 11 with the passivation film 12 interposed therebetween. The organic EL device is made up of the electrode layer 13, the organic layer 14 and the electrode layer 15. Namely, the electrode layer 13, the organic layer 14 and the electrode layer 15 are sequentially formed (stacked) in this order from below over the passivation film 12 over the substrate 11, and the electrode layer 13, the organic layer 14 and the electrode layer 15 form the organic EL device.

The electrode layer 13 is a lower electrode layer, and the electrode layer 15 is an upper electrode layer. The electrode layer 13 forms one of an anode and a cathode, and the electrode layer 15 forms the other of the anode and the cathode. Namely, when the electrode layer 13 is an anode (anode layer), the electrode layer 15 is a cathode (cathode layer), and when the electrode layer 13 is a cathode (cathode layer), the electrode layer 15 is an anode (anode layer). Each of the electrode layer 13 and the electrode layer 15 is made of a conductive film.

One of the electrode layer 13 and the electrode layer 15 is desirably composed of a metal film such as an aluminum film (Al film) so as to be able to function as a reflection electrode. Also, the other of the electrode layer 13 and the electrode layer 15 is desirably composed of a transparent conductor film made of ITO (indium tin oxide) or the like so as to be able to function as a transparent electrode. When the so-called bottom emission type in which light is emitted from a lower surface side of the substrate 11 is adopted, the electrode layer 13 can be formed as the transparent electrode. On the other hand, when the so-called top emission type in which light is emitted from an upper surface side of the substrate 11 is adopted, the electrode layer 15 can be formed as the transparent electrode. In addition, when the bottom emission type is adopted, a transparent substrate (transparent flexible substrate) having translucency can be used as the substrate 11.

Since the electrode layer 13 is formed over the passivation film 12 over the substrate 11, the organic layer 14 is formed over the electrode layer 13, and the electrode layer 15 is formed over the organic layer 14, the organic layer 14 is interposed between the electrode layer 13 and the electrode layer 15.

The organic layer 14 includes at least an organic light emitting layer. The organic layer 14 can further include any of a hole transport layer, a hole implantation layer, an electron transport layer, and an electron implantation layer as needed in addition to the organic light emitting layer. Therefore, for example, the organic layer 14 is configured to have a single layer structure of an organic light emitting layer, a stacked layer structure including a hole transport layer, an organic light emitting layer, and an electron transport layer, or a stacked layer structure including a hole implantation layer, a hole transport layer, an organic light emitting layer, an electron transport layer, and an electron implantation layer.

For example, the electrode layer 13 forms a stripe-shaped pattern extending in an x direction. Namely, the electrode layer 13 has a configuration in which a plurality of linear electrodes (electrode patterns) 13a extending in the x direction are arranged in a y direction at predetermined intervals. The electrode layer 15 forms a stripe-shaped pattern extending in the y direction. Namely, the electrode layer 15 has a configuration in which a plurality of linear electrodes (electrode patterns) 15a extending in the y direction are arranged in the x direction at predetermined intervals. In other words, the electrode layer 13 is made up of a stripe-shaped electrode group extending in the x direction, and the electrode layer 15 is made up of a stripe-shaped electrode group extending in the y direction. Here, the x direction and the y direction are directions intersecting with each other, more specifically, directions orthogonal to each other. Also, the x direction and the y direction are directions substantially parallel to the upper surface of the substrate 11.

Since the extending direction of the respective electrodes 15a constituting the electrode layer 15 is the Y direction and the extending direction of the respective electrodes 13a constituting the electrode layer 13 is the X direction, the electrodes 15a and the electrodes 13a mutually intersect with one another in plan view. Note that “in plan view” means the case of being seen on a plane substantially parallel to the upper surface of the substrate 11. At each intersection portion between the electrode 15a and the electrode 13a, the organic layer 14 is sandwiched by the electrode 15a and the electrode 13a disposed one above the other. Accordingly, at each intersection portion between the electrode 15a and the electrode 13a, the organic EL device (organic EL device constituting the pixel) made up of the electrode 13a, the electrode 15a, and the organic layer 14 between the electrodes 13a and 15a is formed, and the organic EL device forms the pixel. By applying a predetermined voltage between the electrode 15a and the electrode 13a, the organic light emitting layer in the organic layer 14 sandwiched between the electrode 15a and the electrode 13a emits light. In other words, the organic EL device forming each of the pixels can emit light. The electrode 15a functions as the upper electrode (one of the anode and the cathode) of the organic EL device, and the electrode 13a functions as the lower electrode (the other one of the anode and the cathode) of the organic EL device.

Note that the organic layer 14 may be formed over the entire display unit 2, and may be formed to have the same pattern as the electrode layer 13 (that is, the same pattern as the plurality of electrodes 13a constituting the electrode layer 13) or may be formed to have the same pattern as the electrode layer 15 (that is, the same pattern as the plurality of electrodes 15a constituting the electrode layer 15). In any case, the organic layer 14 is present at each intersection portion between the plurality of electrodes 13a constituting the electrode layer 13 and the plurality of electrodes 15a constituting the electrode layer 15.

As described above, in the display unit 2 of the display apparatus 1, the plurality of organic EL devices (pixels) are arranged in an array over the substrate 11 in plan view.

Note that the case where the electrode layers 13 and 15 are configured to have stripe-shaped patterns is described here. Therefore, in the plurality of organic EL devices (pixels) arranged in an array, the lower electrodes (electrodes 13a) are mutually connected to each other in the organic EL devices arranged in the x direction, and the upper electrodes (electrodes 15a) are mutually connected to each other in the organic EL devices arranged in the y direction. However, the structure of the organic EL devices arranged in an array is not limited to this and can be changed in various ways.

For example, the case where the plurality of organic EL devices arranged in an array are not connected by any of the upper electrode and the lower electrode and are arranged independently is also possible. In this case, each of the organic EL devices is formed of an isolated pattern having a stacked layer structure of the lower electrode, the organic layer, and the upper electrode, and a plurality of the isolated organic EL devices are arranged in an array. In this case, in each pixel, an active device such as a TFT (Thin Film Transistor) is provided in addition to the organic EL device, and the pixels can be connected through wirings as needed.

The protection film (protection layer) 16 is formed over the upper surface of the substrate 11 (passivation film 12) so as to cover the organic EL devices, that is, the electrode layer 13, the organic layer 14, and the electrode layer 15. In the present embodiment, the protection film 16 is made of an SiOC film formed by the organic ALD method described in the first embodiment (see FIG. 3 and FIG. 4). This SiOC film is an organic film containing carbon (C) formed by the ALD method using a compound containing Si and C as a material as described above. Moreover, the above-mentioned compound containing Si and C has the characteristics of (1) at least one or more C atoms are provided in a main chain between Si atom and Si atom and (2) amino groups are respectively bonded to Si atoms on both ends of the main chain.

In the case where the organic EL devices are arranged in an array in the display unit 2, the above-mentioned protection film 16 is formed so as to cover the organic EL devices arranged in an array. Therefore, the protection film 16 is preferably formed over the entire display unit 2, and is preferably formed substantially over the entire upper surface of the substrate 11. By covering the organic EL devices (electrode layer 13, organic layer 14 and electrode layer 15) with the protection film 16, the organic EL devices (electrode layer 13, organic layer 14 and electrode layer 15) can be protected, and transmission of moisture to the organic EL devices, in particular, to the organic layer 14 can be prevented (blocked) by the protection film 16. Moreover, since the protection film 16 has flexibility, it also exerts a function as a buffering member. For example, it alleviates a stress between the protection film 16 and the organic EL formation layer (13, 14, 15 or the like) as a lower layer thereof. Moreover, it also alleviates a stress between the protection film 16 and a resin film 17 as an upper layer thereof.

Here, in the case where a part of the electrode, the wiring or the like is exposed from the protection film 16, the protection film 16 is partially removed by a patterning process of the protection film 16 to be described later, and a part of the electrode, the wiring or the like is exposed. However, even in such a case, the organic layer 14 is preferably prevented from being exposed from the region where no protection film 16 is formed.

The resin film (resin layer, resin insulating film, organic insulating film) 17 is formed over the protection film 16. As the material of the resin film 17, for example, PET (polyethylene terephthalate) or the like can be suitably used. The formation of the resin film 17 may be omitted.

<Manufacturing Method of Display Apparatus>

The manufacturing method of the display apparatus 1 according to the present embodiment will be described with reference to drawings. FIG. 8 to FIG. 13 are cross-sectional views each showing an essential part of the manufacturing process of the display apparatus 1 according to the present embodiment. Note that the manufacturing process of the display unit 2 of the display apparatus 1 will be mainly described here.

As shown in FIG. 8, a substrate 10 formed by bonding a glass substrate 9 and a substrate 11 serving as a flexible substrate to each other is prepared (provided). The substrate 11 has flexibility; however, since the substrate 11 is bonded to the glass substrate 9, the substrate 11 is fixed to the glass substrate 9. Thus, the formation of various kinds of films over the substrate 11 and the processing or the like of the films are facilitated. Note that the lower surface of the substrate 11 is bonded to the glass substrate 9.

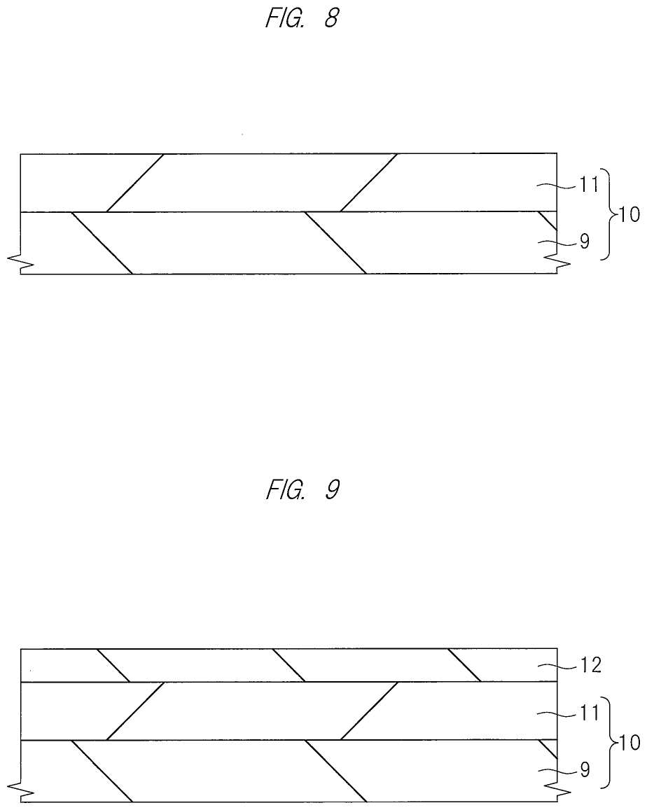

Next, as shown in FIG. 9, the passivation film 12 is formed over the upper surface of the substrate 10. Note that the upper surface of the substrate 10 is synonymous with the upper surface of the substrate 11.

The passivation film 12 can be formed by using the sputtering method, the CVD method, the ALD method or the like. The passivation film 12 is made of an insulating material, for example, a silicon oxide film. For example, the silicon oxide film formed by the CVD method can be suitably used as the passivation film 12.

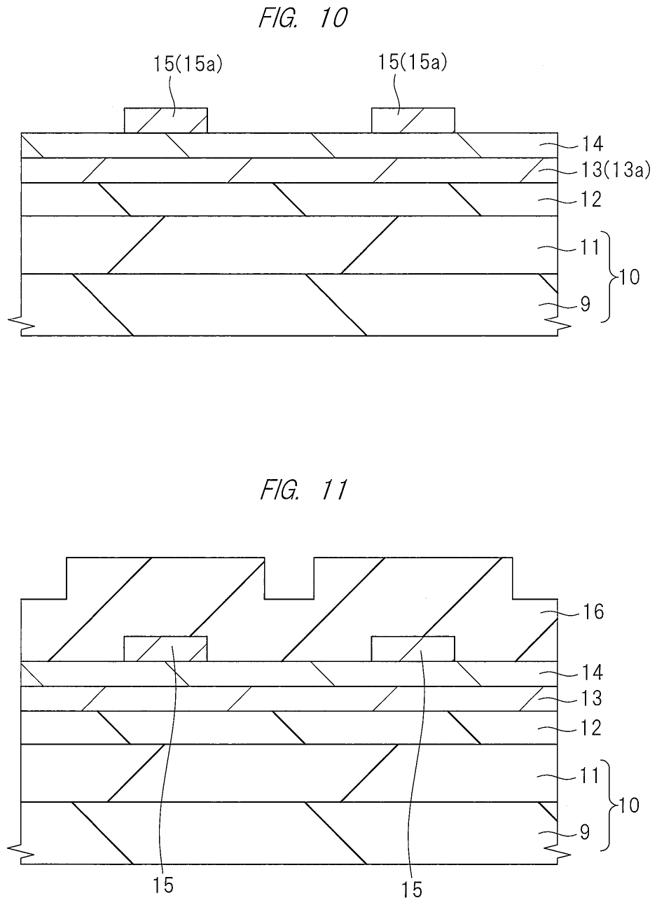

Next, as shown in FIG. 10, an organic EL device made up of the electrode layer 13, the organic layer 14 over the electrode layer 13 and the electrode layer 15 over the organic layer 14 is formed over the upper surface of the substrate 10, that is, over the passivation film 12. Namely, the electrode layer 13, the organic layer 14 and the electrode layer 15 are sequentially formed over the passivation film 12. For example, this process can be carried out in the following manner.

That is, the electrode layer 13 is formed over the upper surface of the substrate 10, that is, over the passivation film 12. For example, the electrode layer 13 can be formed by forming a conductive film over the passivation film 12 and then patterning this conductive film by a photolithography technique, an etching technique or the like. Then, the organic layer 14 is formed over the electrode layer 13. The organic layer 14 can be formed by, for example, a vapor deposition method using a mask (mask vapor deposition method) or the like. Thereafter, the electrode layer 15 is formed over the organic layer 14. The electrode layer 15 can be formed by, for example, the vapor deposition method using a mask or the like. Note that the organic layer 14 and the electrode layer 15 may be processed by patterning.

After the organic EL device made up of the electrode layer 13, the organic layer 14 and the electrode layer 15 has been formed, the protection film 16 is formed over the upper surface of the substrate 10, that is, over the electrode layer 15. The protection film 16 is formed so as to cover the organic EL device.

As described in the first embodiment, the protection film 16 is formed by using the ALD method.

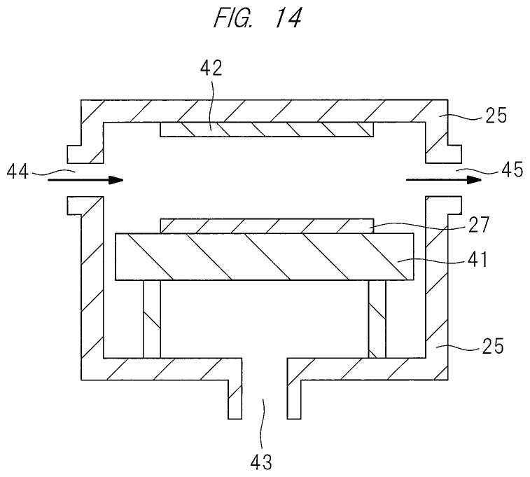

FIG. 14 is a cross-sectional view showing one example of a configuration of a chamber (processing chamber) 25 for forming a film by the ALD method.

As shown in FIG. 14, a stage 41 over which a processing object 27 is disposed and an upper electrode 42 disposed above the stage 41 are provided in the chamber 25. An exhaustion part (exhaustion port) 43 of the chamber 25 is connected to a vacuum pump (not shown) or the like, so that the inside of the chamber 25 can be controlled to a predetermined pressure. Moreover, the chamber 25 includes a gas introduction part 44 for introducing a gas into the chamber 25 and a gas discharging part 45 for discharging a gas from the inside of the chamber 25. Note that, in FIG. 14, for simplicity of understanding, the flow of gas to be introduced from the gas introduction part 44 into the chamber 25 and the flow of gas to be discharged from the gas discharging part 45 to the outside of the chamber 25 are schematically indicated by arrows, respectively. By using the apparatus having this configuration, the protection film (PRO, 16) is formed as described in the first embodiment in detail (see FIG. 3 and FIG. 4).

Moreover, in the case where a part of the electrode, the wiring or the like needs to be exposed from the protection film 16, a part of the electrode, the wiring or the like can be exposed by patterning the protection film 16 by a photolithography technique, an etching technique or the like after forming the protection film 16. As described above, a silicon-based compound such as SiO₂, SiOC or the like can be easily processed by dry etching and is superior in processability. In contrast, for example, Alcone such as aluminum oxide or the like is difficult to be processed by dry etching, needs to use the method (mask vapor deposition method) in which a region where no protection film 16 is to be formed is covered with a mask and aluminum oxide (Alcone) is formed as the protection film 16 in an exposed region not covered with the mask, and is inferior in processability.

Since the organic EL device (in particular, the organic layer 14) is weak at high temperature, the film-forming temperature after the formation of the organic layer 14 is preferably set to a comparatively low temperature so as not to give adverse effects to the organic EL device (in particular, the organic layer 14). Specifically, the film-forming temperature is preferably set to 300° C. or lower, and more preferably to 200° C. or lower. For example, as described also in the first embodiment, the film-forming temperature of the above-mentioned protection film 16 is 200° C. or lower. As described above, according to the present embodiment, the protection film 16 having a moisture barrier property and flexibility can be formed even at a comparatively low film-forming temperature.

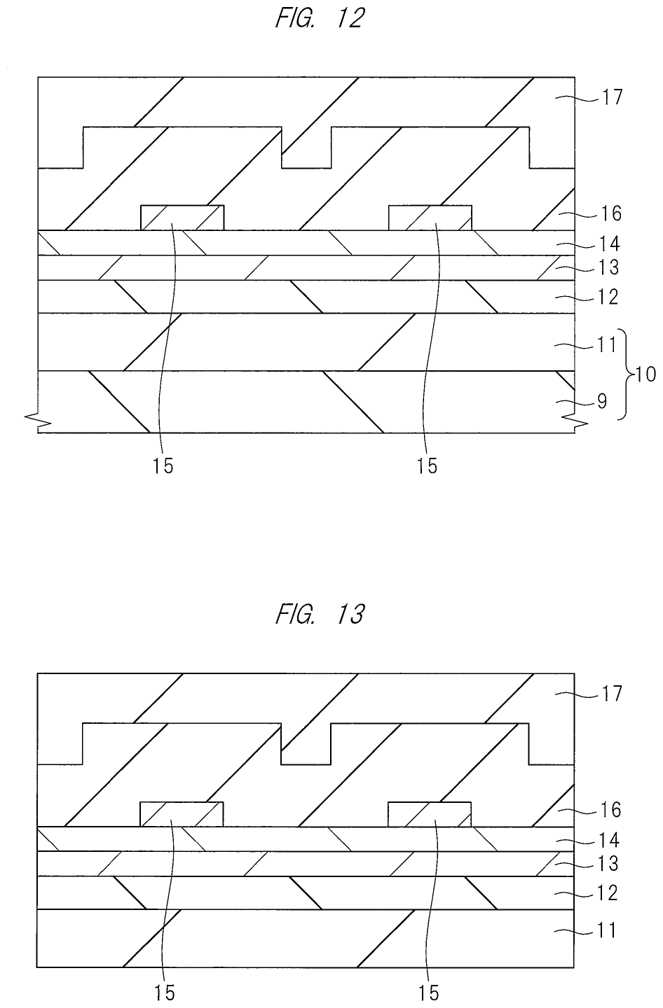

After forming the protection film 16, as shown in FIG. 12, the resin film 17 is formed over the upper surface of the substrate 10, that is, over the protection film 16. The resin film 17 is made of PET or the like and can be formed by the spin coating method (coating method) or the like.

Thereafter, as shown in FIG. 13, by peeling the substrate 11 off from the glass substrate 9, the substrate 11 and the structural body over the upper surface thereof are separated from the glass substrate 9. Thus, the display apparatus 1 can be manufactured.

Note that, in the manufacturing process of the display apparatus, undesired silicon-based compound such as SiO₂, SiOC or the like adhered to the side walls or the like of the aforementioned chamber 25 may be cleaned (removed). As described earlier, since silicon-based compound such as SiO₂, SiOC or the like can be easily removed by dry etching, cleaning inside the chamber 25 can be carried out by allowing an etching gas to flow into the chamber 25, and maintenance of the chamber 25 can be easily carried out.

### Application Example

FIG. 15 is a diagram showing a foreign matter 31 over the organic EL formation layer L. The organic EL formation layer L corresponds to, for example, a layer obtained by combining the substrate 10, the passivation film 12, the electrode layer 13, the organic layer 14 and the electrode layer 15 shown in FIG. 10 with each other.

As shown in FIG. 15, a foreign matter (particle) 31 sometimes adheres to the surface of the organic EL formation layer L. The occurrence rate of the foreign matter 31 is desirably kept low; however, itis difficult to make the occurrence rate zero. Therefore, measures for avoiding problems at the time of occurrence of the foreign matter 31 as much as possible, while suppressing the occurrence rate of the foreign matter 31, are demanded. As one of the measures, a method of fixing the foreign matter to a film is proposed.

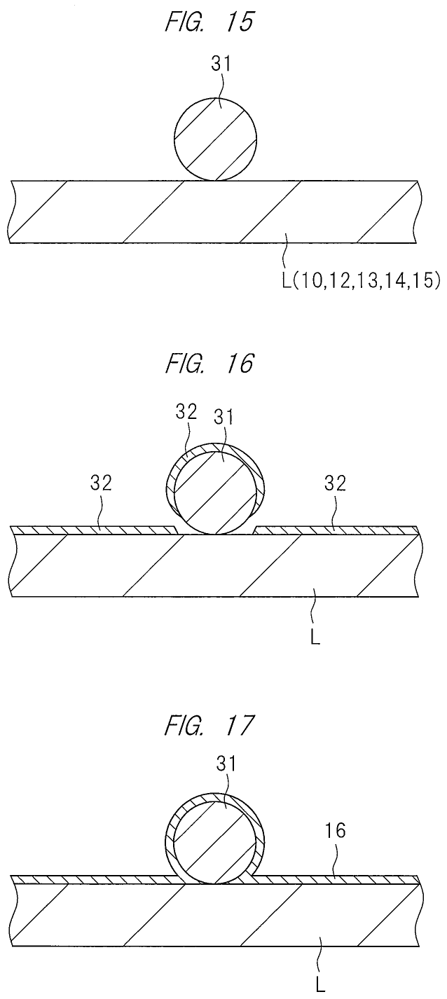

FIG. 16 is a diagram showing a case where a protection film is formed over the foreign matter over the organic EL formation layer by using the CVD method, and FIG. 17 is a diagram showing a case where a protection film is formed over the foreign matter over the organic EL formation layer by using the ALD method.

As shown in FIG. 16, in the case where a protection film 32 is formed by the CVD method in a state where a foreign matter 31 is adhered to the organic EL formation layer L, the step coverage is low and the continuous protection film 32 cannot be formed so as to fix the foreign matter 31. In other words, no protection film 32 is formed at a part shaded with the foreign matter 31. In this state, there is a concern that moisture might enter through the lower portion of the foreign matter 31. Moreover, the foreign matter 31 is likely to come off, and if the foreign matter 31 has come off in the following process, a hole (opening) corresponding to the size of the foreign matter 31 is generated in the protection film 32, so that the moisture barrier property is further deteriorated.

In contrast, as described in the present embodiment, in the case where the protection film 16 is formed by the ALD method, the step coverage is good as shown in FIG. 17, and it is thus possible to firmly fix the foreign matter 31 and properly maintain the moisture barrier property.

### Third Embodiment

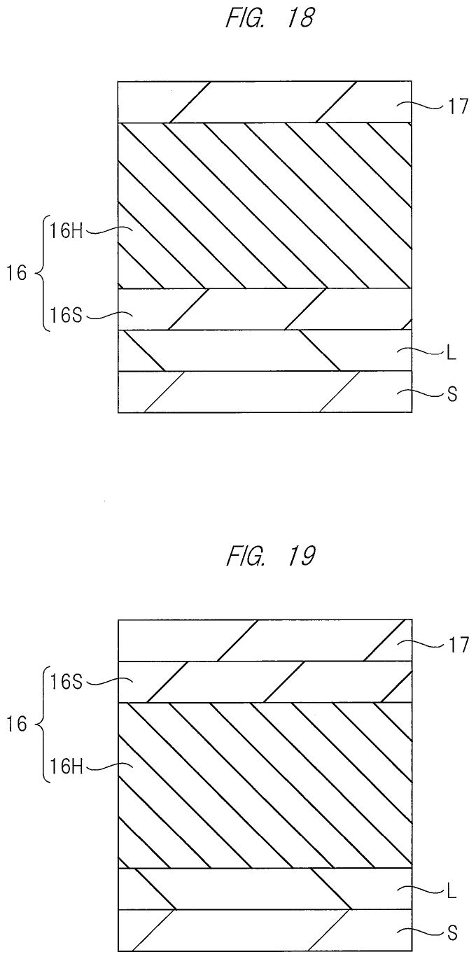

In the first and second embodiments, the case where the protection film (PRO, 16) is a single layer film has been described; however, the protection film may be prepared as a stacked film. For example, the protection film may be formed as a stacked film composed of SiOC film/inorganic insulating film, inorganic insulating film/SiOC film, SiOC film/inorganic insulating film/SiOC film, or inorganic insulating film/SiOC film/inorganic insulating film. First to fourth examples of the present embodiment will be described below with reference to FIG. 18 to FIG. 21.

### First Example

FIG. 18 is a cross-sectional view showing a protection film (SiOC film/inorganic insulating film) for an organic EL device according to a first example of the present embodiment. As shown in FIG. 18, in this first example, the protection film 16 is formed as a stacked film composed of an SiOC film (organic insulating film, organic ALD film) 16S and an SiO₂ film (inorganic insulating film, inorganic ALD film) 16H. The SiOC film (organic insulating film, organic ALD film) 16S is formed over the organic EL formation layer L over the flexible substrate S, and the SiO₂ film (inorganic insulating film, inorganic ALD film) 16H is formed over the SiOC film 16S. As described earlier, a film containing carbon (C) is referred to as an organic film, and a method of forming an organic film by the ALD method is referred to as an organic ALD method. In contrast, a method of forming an inorganic film by the ALD method is referred to as an inorganic ALD method.

As described in the first embodiment, the SiOC film 16S can be formed by, for example, the organic ALD method using 1,2-bis[(dimethylamino)dimethylsilyl]ethane and O-plasma. This SiOC film 16S exerts a moisture barrier property and has flexibility.

The SiO₂ film 16H can be formed by, for example, the inorganic ALD method using bis [(dimethylamino) silane and O-plasma. Although this SiO₂ film 16H is inferior in flexibility, it has a dense structure and a high moisture barrier property. As described above, the inorganic insulating film such as the SiO₂ film 16H has a denser structure and is harder (higher in hardness) than the organic insulating film such as the SiOC film 16S. The hardness can be measured by, for example, the pencil hardness method or the like. Moreover, the organic insulating film like the SiOC film 16S has a smaller curvature radius when it is bent by applying a predetermined pressure and a higher bending resistance in comparison with the inorganic insulating film like the SiO₂ film 16H. Here, the bending resistance refers to crack occurrence resistance at the time of bending, and the presence or absence of the occurrence of cracks after being bent is evaluated by visual inspection and water resistant property (presence or absence of water leakage).

As described above, the moisture barrier property is improved by stacking the SiOC film 16S and the SiO₂ film 16H. Moreover, since the SiOC film 16S has flexibility and thus has a function as a buffering member, it alleviates a stress between the SiO₂ film 16H and the organic EL formation layer L.

For example, after forming the SiOC film 16S by repeating the first step, the second step, the third step and the fourth step described with reference to FIG. 4 in the first embodiment for a plurality of cycles, the SiO₂ film 16H is formed by the inorganic ALD method using bis(dimethylamino) silane and O-plasma. At this time, by using the chamber (processing chamber) 25 described with reference to FIG. 14, the SiOC film 16S and the SiO₂ film 16H can be successively formed.

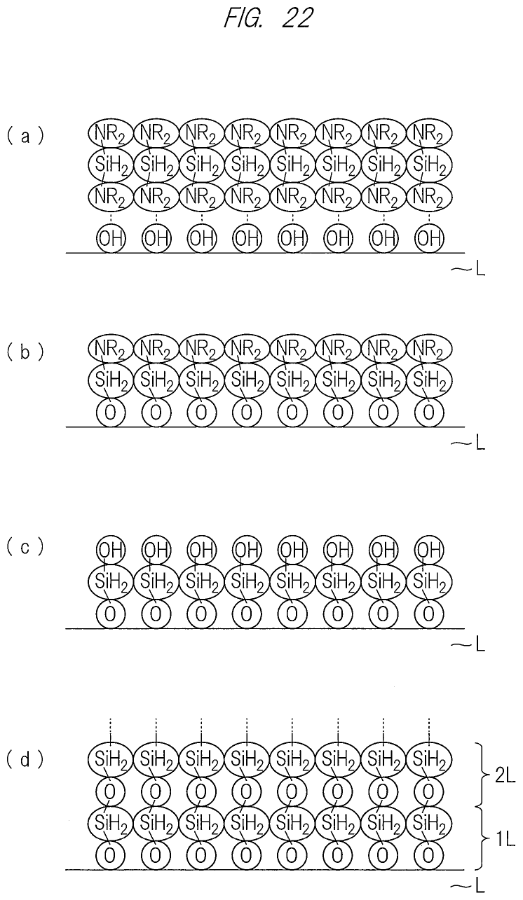

For example, in the first to fourth steps described with reference to FIG. 4, after forming the SiOC film 16S by using a source gas of 1,2-bis[(dimethylamino)dimethylsilyl]ethane, the SiO₂ film 16H is formed by performing the similar process while changing the source gas to bis(dimethylamino)silane. FIG. 22(a) to FIG. 22(d) are diagrams schematically showing a state of a formation of an SiO₂ film by the ALD method using bis(dimethylamino)silane.

First, as a first step (source gas supply step), bis(dimethylamino)silane serving as a source gas is introduced (supplied) into the chamber in which a substrate is disposed. Thus, —OH on the surface of the organic EL formation layer L serving as the processing object and an amino group at one of the ends of bis(dimethylamino)silane are chemically bonded to each other moderately (FIG. 22(a)).

Next, as a second step (purging step), the introduction of the source gas into the chamber is stopped, and a purge gas is introduced (supplied). As the purge gas, an inert gas is suitably used; however, a nitrogen gas (N₂ gas) may be used in some cases. By introducing the purge gas, the source gas other than the bis(dimethylamino)silane that is chemically bonded moderately with —OH on the surface of the organic EL formation layer L is discharged to the outside of the chamber together with the purge gas. In this second step, by the heat treatment at 200° C. or lower, —OH on the surface of the organic EL formation layer L and an amino group at one of the ends of the bis(dimethylamino)silane chemically react with each other, so that NR₂H (R=CH₃) is separated and O (oxygen atom) and Si (silicon atom) are bonded to each other (FIG. 22(b)).

Next, as a third step (reaction gas supply step), a reaction gas is introduced (supplied) into the chamber. As the reaction gas, O-plasma may be used. In this case, an O₂ gas (oxygen gas) is introduced into the chamber, and O-plasma is generated by applying high-frequency power. Note that O-plasma preliminarily generated outside the chamber may be introduced (supplied) into the chamber. By the action of this O-plasma, an amino group on the other end of bis(dimethylamino)silane becomes —OH (FIG. 22(c)). Thus, an atomic layer (first layer 1L) of SiO is formed over the surface of the organic EL formation layer L.

Next, as a fourth step (purging step), the introduction of the reaction gas into the chamber and the application of the high-frequency power are stopped, and a purge gas is introduced (supplied) into the chamber. As the purge gas, an inert gas can be suitably used; however, a nitrogen gas (N₂ gas) may be used in some cases. By introducing the purge gas, an unreacted substance (reaction gas or the like) is discharged (purged) to the outside of the chamber together with the purge gas.

Next, by carrying out the first step, the second step, the third step and the fourth step in the same manner, an atomic layer (second layer 2L) of SiO is formed (FIG. 22(d)).

As described above, by repeating the first, second, third and fourth steps for a plurality of cycles, an SiOC film having a desired film thickness can be formed over the surface of the organic EL formation layer L. For example, if the first, second, third and fourth steps are repeated for 30 cycles, a film composed of 30 atomic layers can be formed.

Note that, in FIG. 22, a reaction in which mutual Si atoms between adjacent atoms are directly bonded to each other or are bonded with an oxygen atom interposed therebetween may be generated.

As described above, in the present embodiment, by switching the source gases, a stacked film of the SiOC film 16S having flexibility and the SiO₂ film 16H having a dense structure can be formed.

### Second Example

FIG. 19 is a cross-sectional view showing a protection film (inorganic insulating film/SiOC film) for an organic EL device according to a second example of the present embodiment. As shown in FIG. 19, in this second example, the protection film 16 is made up of a stacked film composed of the SiO₂ film (inorganic insulating film, inorganic ALD film) 16H and the SiOC film (organic insulating film, organic ALD film) 16S. The SiO₂ film (inorganic insulating film, inorganic ALD film) 16H is formed over the organic EL formation layer L over the flexible substrate S and the SiOC film (organic insulating film, organic ALD film) 16S is formed over the SiO₂ film 16H.

In the same manner as the first example, the SiO₂ film 16H can be formed by, for example, the inorganic ALD method using bis(dimethylamino)silane and O-plasma, and the SiOC film 16S can be formed by, for example, the organic ALD method using 1,2-bis[(dimethylamino)dimethylsilyl]ethane and O-plasma.

Also in this application example, the moisture barrier property can be improved by stacking the SiO₂ film 16H and the SiOC film 16S. Moreover, since the SiOC film 16S has flexibility and thus has a function as a buffering member, it alleviates a stress between the SiO₂ film 16H and the resin film 17.

### Third Example

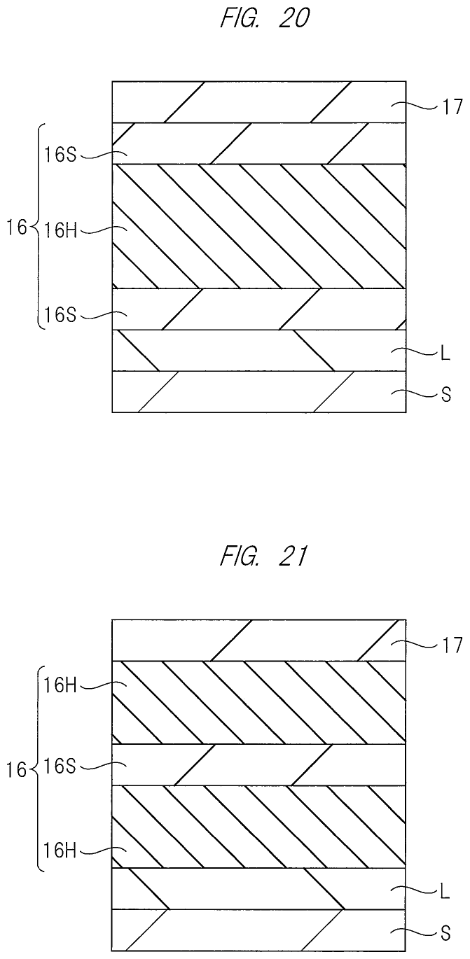

FIG. 20 is a cross-sectional view showing a protection film for an organic EL device according to a third example of the present embodiment. As shown in FIG. 20, in this third example, the protection film 16 is made up of a stacked film composed of the SiOC film (organic insulating film, organic ALD film) 16S, the SiO₂ film (inorganic insulating film, inorganic ALD film) 16H and the SiOC film (organic insulating film, organic ALD film) 16S. The SiOC film (organic insulating film, organic ALD film) 16S is formed over the organic EL formation layer L over the flexible substrate S, the SiO₂ film (inorganic insulating film, inorganic ALD film) 16H is formed over the SiOC film 16S, and the SiOC film (organic insulating film, organic ALD film) 16S is formed over the SiO₂ film 16H.

In the same manner as the first example, the SiO₂ film 16H can be formed by, for example, the inorganic ALD method using bis(dimethylamino)silane and O-plasma, and the SiOC film 16S can be formed by, for example, the organic ALD method using 1,2-bis[(dimethylamino)dimethylsilyl]ethane and O-plasma.

Also in this application example, the moisture barrier property can be improved by stacking the SiOC film 16S, the SiO₂ film 16H and the SiOC film 16S. Moreover, since the SiOC film 16S has flexibility and thus has a function as a buffering member, it alleviates a stress between the organic EL formation layer L and the SiO₂ film 16H. Moreover, it also alleviates a stress between the SiO₂ film 16H and the resin film 17.

### Fourth Example

FIG. 21 is a cross-sectional view showing a protection film for an organic EL device according to a fourth example of the present embodiment. As shown in FIG. 21, in this fourth example, the protection film 16 is made up of a stacked film composed of the SiO₂ film (inorganic insulating film, inorganic ALD film) 16H, the SiOC film (organic insulating film, organic ALD film) 16S and the SiO₂ film (inorganic insulating film, inorganic ALD film) 16H. The SiO₂ film (inorganic insulating film, inorganic ALD film) 16H is formed over the organic EL formation layer L over the flexible substrate S, the SiOC film (organic insulating film, organic ALD film) 16S is formed over the SiO₂ film 16H, and the SiO₂ film (inorganic insulating film, inorganic ALD film) 16H is formed over the SiOC film 16S.

In the same manner as the first example, the SiO₂ film 16H can be formed by, for example, the inorganic ALD method using bis(dimethylamino)silane and O-plasma, and the SiOC film 16S can be formed by, for example, the organic ALD method using 1,2-bis[(dimethylamino)dimethylsilyl]ethane and O-plasma.

Also in this application example, the moisture barrier property can be improved by stacking the SiO₂ film 16H, the SiOC film 16S and the SiO₂ film 16H. Moreover, since the SiOC film 16S has flexibility and thus has a function as a buffering member, it alleviates a stress between the SiO₂ films 16H.

### OTHER EXAMPLES

In the above-mentioned first to fourth examples, the SiO₂ film has been exemplified as the inorganic insulating film; however, a stacked film composed of an SiOC film and another inorganic insulating film may be used as the protection film. As the inorganic insulating film, an SiN film, an Al₂O₃ film, a TiO₂ film, a ZrO₂ film or the like may be used in addition to the SiO₂ film. These films can be formed by the ALD method. Moreover, among these films, the SiO₂ film and the SiN film can be processed by dry etching and are superior in processability as the protection film, and cleaning of the chamber can be easily carried out.

### Fourth Embodiment

A specific example will be described in this embodiment.

### Example

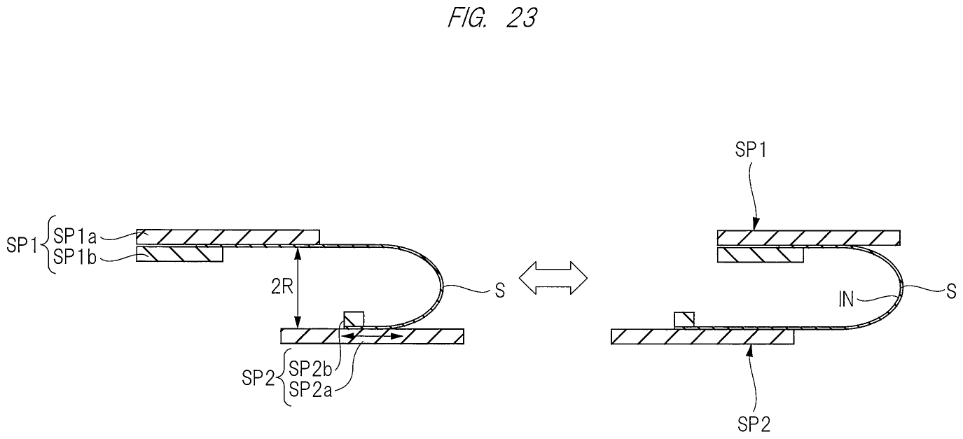

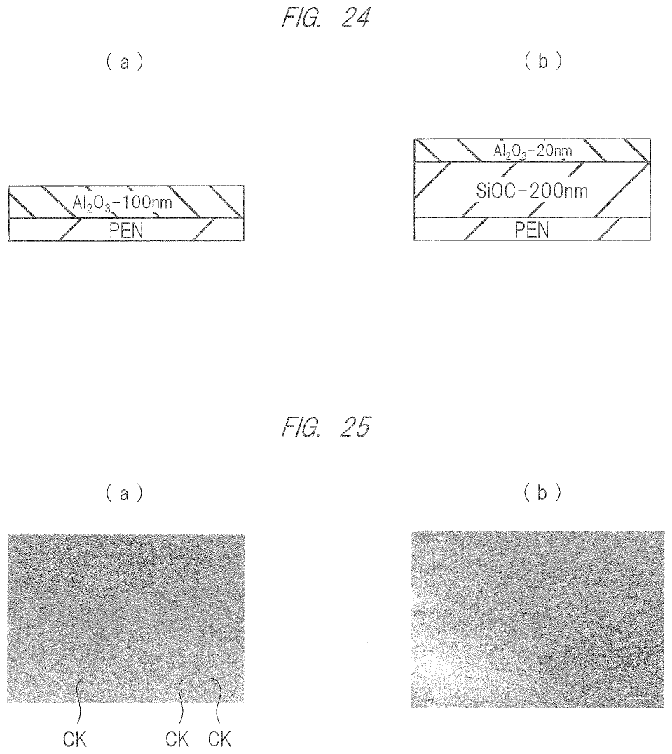

The results of bending test of a PEN substrate in which an SiOC film and an Al₂O₃ film are stacked will be described below. The stacked film of the SiOC film and the Al₂O₃ film corresponds to, for example, “the SiOC film/inorganic insulating film” described in the third embodiment. FIG. 23 is a schematic diagram showing a state of the bending test. FIG. 24(a) and FIG. 24(b) are cross-sectional views showing a PEN substrate in which an SiOC film and an Al₂O₃ film are stacked and a PEN substrate in which an Al₂O₃ film is formed as a single layer. FIG. 25(a) and FIG. 25(b) are surface photographs after the bending test of the PEN substrate in which an SiOC film and an Al₂O₃ film are stacked and the PEN substrate in which an Al₂O₃ film is formed as a single layer.

<Film-Forming Process>

An SiOC film and an Al₂O₃ film are sequentially formed over a PEN substrate through the process described below (see FIG. 24(b)). The PEN substrate is a flexible substrate made of polyethylene naphthalate (PEN).

First, an SiOC film is formed over the PEN substrate by the ALD method. 1,2-bis[dimethylamino)dimethylsilyl]ethane (the aforementioned “DMSE”) serving as a source gas is introduced into a chamber in which the PEN substrate is disposed (St1). Next, the introduction of the source gas into the chamber is stopped, and a nitrogen gas is introduced as a purge gas (St2). Next, an O₂ gas (oxygen gas) serving as a reaction gas is introduced into the chamber, and O-plasma is generated by applying high-frequency power (St3). Next, the introduction of the reaction gas into the chamber and the application of the high-frequency power are stopped, and a nitrogen gas serving as a purge gas is introduced into the chamber (St4).

Next, by carrying out the above-mentioned St1 to St4 for 50 cycles, 50 atomic layers made of SiOC are formed as the SiOC film. The film thickness of the SiOC film is about 200 nm.

Next, an Al₂O₃ film (alumina film) is formed over the SiOC film by the ALD method. Trimethyl aluminum serving as a source gas is introduced into the chamber in which the PEN substrate is disposed (St11). Next, the introduction of the source gas into the chamber is stopped and a nitrogen gas serving as a purge gas is introduced (St12). Next, an O₂ gas (oxygen gas) serving as a reaction gas is introduced into the chamber, and O-plasma is generated by applying high-frequency power (St13). Next, the introduction of the reaction gas into the chamber and the application of the high-frequency power are stopped, and a nitrogen gas serving as a purge gas is introduced into the chamber (St14).

Next, by carrying out the above-mentioned St11 to St14 for 120 cycles, 120 atomic layers made of Al₂O₃ are formed as the Al₂O₃ film. The film thickness of the Al₂O₃ film is about 20 nm.

### Comparative Example

As a comparative example, an Al₂O₃ film is formed as a single layer over the PEN substrate by the ALD method (see FIG. 24(a)). The Al₂O₃ film is formed over the PEN substrate by the ALD method. Trimethyl aluminum serving as a source gas is introduced into a chamber in which the PEN substrate is disposed (St11). Next, the introduction of the source gas into the chamber is stopped and a nitrogen gas serving as a purge gas is introduced (St12). Next, an O₂ gas (oxygen gas) serving as a reaction gas is introduced into the chamber, and O-plasma is generated by applying high-frequency power (St13). Next, the introduction of the reaction gas into the chamber and the application of the high-frequency power are stopped, and a nitrogen gas serving as a purge gas is introduced into the chamber (St14).

Next, by carrying out the above-mentioned St11 to St14 for 600 cycles, 600 atomic layers made of Al₂O₃ are formed as the Al₂O₃ film. The film thickness of the Al₂O₃ film is about 100 nm.

<Evaluation: Bending Test>

With respect to flexibility of the PEN substrate formed by stacking the SiOC film and the Al₂O₃ film, evaluation was carried out by using a bending tester. As shown in FIG. 23, a substrate (in this case, the PEN substrate) S was held by a supporting part SP1 and a supporting part SP2 while being bent with a radius R. In the bent portion, the inner side IN corresponded to a film forming surface. Moreover, in the supporting part SP1, one end of the substrate S was sandwiched between a supporting portion SP1a and a supporting portion SP1b. Furthermore, in the supporting part SP2, the other end of the substrate S was sandwiched between a supporting portion SP2a and a supporting portion SP2b. Then, a bending stress was applied to the substrate S by moving the supporting portion SP2a laterally.

Under the conditions of the curvature radius R set to 4 mm and the moving distance of the supporting portion SP2 set to 8 cm, the supporting portion SP2 was reciprocally moved 10,000 times at the rate of one time per one second, and then the surface was observed. The same test was carried out on the comparative example in which an Al₂O₃ film was formed as the single layer.

In FIG. 24 and FIG. 25, FIG. 24(b) and FIG. 25(b) correspond to the PEN substrate (example) on which the SiOC film and the Al₂O₃ film are stacked, and FIG. 24(a) and FIG. 25(a) correspond to the PEN substrate (comparative example) on which the Al₂O₃ film is formed as a single layer.

As shown in FIG. 25(b), in the case of the PEN substrate (example) on which the SiOC film and the Al₂O₃ film were stacked, no cracks were visually observed even after carrying out the above-mentioned bending test. On the other hand, as shown in FIG. 25(a), in the case of the PEN substrate (comparative example) on which the Al₂O₃ film was formed as a single layer, cracks CK were observed.

As described above, improvement in flexibility by the formation of the SiOC film was confirmed. Namely, the function of the SiOC film as a buffering member was confirmed. Moreover, the film thickness of 200 nm was ensured in 50 cycles, and the thickness of the atomic layer per cycle was increased. Namely, the improvement in the film-forming speed of the SiOC film was confirmed.

In the foregoing, the invention made by the inventors of the present invention has been concretely described based on the embodiments. However, it is needless to say that the present invention is not limited to the foregoing embodiments and various modifications can be made within the scope of the present invention.

### REFERENCE SIGNS LIST

1: display apparatus
1L: first layer
2: display unit
2L: second layer
3: circuit unit
4: region
9: glass substrate
10: substrate
11: substrate
12: passivation film
13: electrode layer
13a: electrode
14: organic layer
15: electrode layer
15a: electrode
16: protection film
16H: SiO₂ film
16S: SiOC film
17: resin film
25: chamber
27: processing object
31: foreign matter
32: protection film
41: stage
42: upper electrode
43: exhaustion part (exhaustion port)
44: gas introduction part
45: gas discharging part
IN: inner side
L: organic EL formation layer
PRO: protection film
S: flexible substrate
SP1: supporting part
SP1a, SP1b: supporting portion
SP2: supporting part
SP2a, SP2b: supporting portion

1. A forming method of a protection film for an organic EL device comprising the steps of:
(a) forming an organic EL device over a flexible substrate; and
(b) forming a protection film including an SiOC film so as to cover the organic EL device,
wherein the SiOC film is formed by an ALD method using a compound containing Si and C as a material,
the compound containing Si and C has at least one or more C atoms in a main chain between Si atom and Si atom, and
amino groups are respectively bonded to the Si atoms on both ends of the main chain.

2. The forming method of a protection film for an organic EL device according to claim 1,
wherein the compound containing Si and C reacts with an oxidant to form the SiOC film.

3. The forming method of a protection film for an organic EL device according to claim 2,
wherein the oxidant is an oxygen radical.

4. The forming method of a protection film for an organic EL device according to claim 3,
wherein the step (b) includes, after disposing the flexible substrate over which the organic EL device is formed in a chamber, the steps of:
(b1) introducing the material into the chamber and adsorbing material molecules to an upper portion of the organic EL device;
(b2) introducing a first purge gas into the chamber and removing material molecules of the material that are not adsorbed from inside of the chamber together with the first purge gas;
(b3) introducing the oxygen radical into the chamber or generating the oxygen radical in the chamber and generating a reactant of the material molecules and the oxygen radical; and
(b4) introducing a second purge gas into the chamber and removing unreacted substances from the inside of the chamber together with the second purge gas.

5. The forming method of a protection film for an organic EL device according to claim 4,
wherein the step (b) is carried out at 200° C. or lower.

6. The forming method of a protection film for an organic EL device according to claim 5,
wherein the SiOC film fixes foreign matters.

7. The forming method of a protection film for an organic EL device according to claim 5,
wherein the protection film includes an inorganic insulating film harder than the SiOC film,
the forming method further comprising the step of
(c) forming the inorganic insulating film before the step (b) or after the step (b).

8. A manufacturing method of a display apparatus comprising the steps of:
(a) forming an organic EL device over a flexible substrate; and
(b) forming a protection film including an SiOC film so as to cover the organic EL device,
wherein the SiOC film is formed by an ALD method using a compound containing Si and C as a material,
the compound containing Si and C has at least one or more C atoms in a main chain between Si atom and Si atom, and
amino groups are respectively bonded to the Si atoms on both ends of the main chain.

9. The manufacturing method of a display apparatus according to claim 8,
wherein the compound containing Si and C reacts with an oxidant to form the SiOC film.

10. The manufacturing method of a display apparatus according to claim 9,
wherein the oxidant is an oxygen radical.

11. The manufacturing method of a display apparatus according to claim 10,
wherein the step (b) includes, after disposing the flexible substrate over which the organic EL device is formed in a chamber, the steps of:
(b1) introducing the material into the chamber and adsorbing material molecules to an upper portion of the organic EL device;
(b2) introducing a first purge gas into the chamber and removing material molecules of the material that are not adsorbed from inside of the chamber together with the first purge gas;
(b3) introducing the oxygen radical into the chamber or generating the oxygen radical in the chamber and generating a reactant of the material molecules and the oxygen radical; and
(b4) introducing a second purge gas into the chamber and removing unreacted substances of the oxygen radical from the inside of the chamber together with the second purge gas.

12. The manufacturing method of a display apparatus according to claim 11,
wherein the step (b3) is carried out at 200° C. or lower.

13. The manufacturing method of a display apparatus according to claim 12,
wherein the SiOC film fixes foreign matters.

14. The manufacturing method of a display apparatus according to claim 12,
wherein the protection film includes an inorganic insulating film harder than the SiOC film,
the manufacturing method further comprising the step of
(c) forming the inorganic insulating film before the step (b) or after the step (b).

15. The manufacturing method of a display apparatus according to claim 14,
wherein the protection film includes any one of stacked films selected from a group of an SiOC film/inorganic insulating film, an inorganic insulating film/SiOC film, an SiOC film/inorganic insulating film/SiOC film and an inorganic insulating film/SiOC film/inorganic insulating film.

16. The manufacturing method of a display apparatus according to claim 15,
wherein the respective films constituting the protection film are successively formed in the chamber.

17. The manufacturing method of a display apparatus according to claim 15, further comprising the step of
(d) removing the protection film adhered to the inside of the chamber after the step (c).

18. The manufacturing method of a display apparatus according to claim 15,
wherein the inorganic insulating film is any one of films selected from a group of an SiO₂ film, an SiN film, an Al₂O₃ film, a TiO₂ film and a ZrO₂ film.

19. A display apparatus comprising:
a flexible substrate;
an organic EL device formed over the flexible substrate; and
a protection film formed so as to cover the organic EL device and including an SiOC film,
wherein the SiOC film is a film formed by an ALD method using a compound containing Si and C as a material,
the compound containing Si and C has at least one or more C atoms in a main chain between Si atom and Si atom, and
amino groups are respectively bonded to the Si atoms on both ends of the main chain.

20. The display apparatus according to claim 19,
wherein the SiOC film is a film formed by a reaction between the compound containing Si and C and an oxygen radical.

21. The display apparatus according to claim 20,
wherein the protection film includes an inorganic insulating film harder than the SiOC film.

22. The display apparatus according to claim 21,
wherein the protection film includes any one of stacked films selected from a group of an SiOC film/inorganic insulating film, an inorganic insulating film/SiOC film, an SiOC film/inorganic insulating film/SiOC film and an inorganic insulating film/SiOC film/inorganic insulating film.

23. The display apparatus according to claim 21,
wherein the inorganic insulating film is any one of films selected from a group of an SiO₂ film, an SiN film, an Al₂O₃ film, a TiO₂ film and a ZrO₂ film.
